(19) United States
(12) Patent Application Publication
(10) Pub. No.: US 2005/0035308 A1
(43) Pub. Date: Feb. 17, 2005

(54) Pattern writing equipment

(75) Inventors: Amin Javer, Cambridge (GB); Timothy Groves, Cambridge (GB)

Correspondence Address: HOUSTON ELISEEVA, 4 MILITIA DRIVE, SUITE 4, LEXINGTON, MA, 02421, US

(73) Assignee: Leica Microsystems Lithography Ltd., Cambridge (GB)

(21) Appl. No.: 10/909,165

(22) Filed: Jul. 30, 2004

(30) Foreign Application Priority Data
Aug. 1, 2003 (GB) GB 03 18 118.7

(51) Int. Cl. H01J 37/302

(52) U.S. Cl. 250/492.22; 250/398

(57) ABSTRACT

Pattern-writing equipment for writing a pattern on the surface of an substrate (S) by electron beam lithography comprises electron beam generating means, such as an electron source (10) and anode (12), focusing means (13, 14, 16, 19, 20) for focusing the beam to produce a writing spot on the substrate surface, and a beam deflector for displacing the writing spot on the substrate surface to trace the pattern to be written. Also present in the equipment are control means for varying the writing spot size to produce a simultaneous increase or simultaneous decrease in both spot size and writing current. The focusing means is distinguished by two lens sets each containing a high focal strength main lens (13 or 14) and a low focal strength auxiliary lens (19 or 20). The control means varies the writing spot size by causing a reciprocal change in the focal strengths of the two auxiliary lens (19, 20) while writing is being carried out.

### RELATED APPLICATIONS

This application claims priority of the British patent application 03 18 118.7 which is incorporated by reference herein.

### FIELD OF THE INVENTION

The present invention relates to a pattern-writing equipment, especially for electron beam lithography.

### BACKGROUND OF THE INVENTION

Electron beam lithography is a well-known method for writing small pattern features particularly in the range of 2 to 200 nanometres on electron-sensitive surfaces of substrates in the production of, inter alia, integrated circuits. This range of resolution is not achievable with conventional light optical lithography. The central problem with existing approaches to electron beam lithography is that it is very slow compared with light optical lithography. There are two fundamental reasons for this, the first of which is that electron beam lithography is a serial process carried out by writing pattern features in sequence by means of a narrow beam, whereas light optical lithography is a highly parallel process exposing a relatively large field with many pattern features in a single flash. The second reason is that the writing speed of electron beam lithography is directly proportional to the beam current and the usable beam current is limited by the Coulomb interaction between beam electrons, which causes loss of resolution as the writing current is increased. The maximum usable writing current, i.e. total instantaneous beam current (measurable in amperes) used to write a pattern, is too low by a factor of approximately 100 to permit a throughput competitive with light optical lithography.

Because of the low throughput of electron beam lithography, it is impractical and/or prohibitively expensive for many applications, especially those involving high volume manufacturing. It would thus be highly desirable to improve throughput so as to enable applications which were previously inaccessible.

The highest resolution in electron beam lithography is obtainable with a Gaussian beam system. In such a system, the electron beam is focussed to a single writing spot with a roughly Gaussian distribution of writing current within the spot. This system therefore writes one pixel at a time, a pixel being the smallest resolution element of a pattern. In this sense a Gaussian beam system is entirely serial in its writing process and consequently, it is the slowest system.

In general, the smaller the writing spot, the smaller the pattern feature able to be written. However, the smaller the writing spot, the lower the beam current and the lower the throughput. Existing Gaussian beam systems maintain the writing spot at a constant size for the entire written pattern. Typical patterns contain a range of pattern feature sizes, i.e. they include some features at the minimum size and some features at larger sizes. Because existing electron beam systems have a constant spot size, which is determined by the smallest feature size, it follows that even large features must be written using this small spot size. This is relatively inefficient, as a small spot is not needed to write a large feature.

Existing electron beam lithography systems typically include means for adjusting the size of the writing spot, which is accomplished by adjustment of lenses in the electron beam path. This is a slow process usually requiring several seconds, as typical electron lenses require a large change in excitation in order to effect a significant change in spot size. The speed at which a change in excitation can be made is inversely related to the size of the change. In order to gain a practical advantage in throughput, it would be necessary to change the spot size much more quickly so that this change can be carried out frequently during pattern writing without adversely affecting throughput.

Another example of prior art systems is that known as variable shaped-beam systems. In this system the spot is typically a rectangle of variable size and aspect ratio. The spot size is made to change quite rapidly during pattern writing. The current density (current per unit area) is constant and independent of spot size. It follows that the writing current is proportional to the area of the writing spot, but because the spot is rectangular the fidelity of pattern writing, although good for features with rectangular symmetry, is inadequate for features with other angles. In the latter case a Gaussian vector beam system is preferred. In addition, the resolution obtainable with a variable shaped-beam system is inferior to that obtainable with a Gaussian beam system and the electron column of a variable shaped-beam system is, of necessity, more complex than the column of a Gaussian system. This has a negative impact on cost and reliability for variable shaped-beam systems.

### SUMMARY OF THE INVENTION

It is accordingly the principal object of the present invention to provide pattern-writing equipment which may allow an increase in writing throughput by way of adaptation of an electron beam writing spot in dependence on pattern features to be written and while writing is in progress.

Other objects and advantages of the invention will be apparent from the following description.

According to the present invention there is provided pattern-writing equipment for writing a pattern on a substrate surface by electron beam lithography, comprising generating means for generating an electron beam, focusing means for focusing the beam to produce a defined writing spot on an electron-sensitive surface of the substrate, displacing means for displacing the writing spot on the surface in correspondence with the pattern to be written and control means for varying the size of the writing spot to produce a simultaneous increase or decrease in both the spot size and the writing current of the beam, characterised in that the focusing means comprises two lens sets arranged in series to focus the beam and each comprising a main lens and an auxiliary lens with a lower focal strength than that of the main lens of the respective set, the control means being operable to vary the writing spot size by reciprocal change in the focal strengths of the auxiliary lenses of the two lens sets during writing of the pattern.

With equipment of this kind it is possible to write small features of a pattern with a small spot and in the same pattern to write large features with a large spot. In this way a significant throughput advantage can be realised. A very small feature can be written entirely or almost entirely using a small spot size, whilst a large feature can be written using a combination of large and small spot sizes. It is desirable to always use a small spot size at the edges of pattern features so as to ensure high pattern fidelity. A large spot size may be used in the pattern interior where no fine detail is located and where pattern fidelity is not an issue. However, there is no advantage in increasing the size of the writing spot without increasing the writing current at the same time. This is due to the fact that writing speed is proportional to writing current. Maintaining the writing current at a constant value therefore does not result in increased throughput, regardless of the size of the writing spot. Consequently, the equipment includes provision for increasing the writing current conjunctively with spot size, thus allowing an increase in throughput.

Preferably, each auxiliary lens is arranged adjacent to the main lens of the respective set and, for preference, directly downstream of that main lens with respect to the beam generating means. Such an arrangement provides a compact construction of each lens set so that, for example, the main and auxiliary lenses can be disposed in a fixed relationship by way of a common support.

In functional terms, the lens sets are preferably arranged to focus the beam at two intermediate crossover foci and the control means is operable to vary the focal strengths of the auxiliary lenses to change the relative spacing of the intermediate foci. The intermediate focus closer to the substrate can, in that case, be caused to remain in a fixed position, whilst the intermediate focus further from the substrate can be displaced towards or away from the fixed focus depending on the change carried out to the spot size.

The control means is preferably operable to change the focal strengths of the auxiliary lenses substantially simultaneously, as a consequence of which there is minimal effect on writing spot position and resolution and consequently no significant pause in writing progress.

The equipment preferably also comprises a pattern-writing control system for supplying pattern-writing data to control displacement of the beam by the displacing means, the control means being operable to vary the focal strengths of the auxiliary lenses in synchronism with the displacement of the beam. Co-operation of the supply of the pattern-writing data and the change in writing spot size in this manner ensures effective dynamic adaptation of the spot size to the area sizes of different features of the pattern to be written.

At least one of the lenses can be an electromagnetic or electrostatic lens, the lenses of both sets preferably being of the same kind. If the at least one electromagnetic or electrostatic lens is an auxiliary lens, such a lens preferably has a coil with minimised inductance so as to assist high-speed switching of the focal strength. In addition, the lens is preferably carried by a support of a high-resistivity alloy or other material.

The control means is preferably operable to vary the size of the writing spot in the sense of an increase within at most substantially 10 milliseconds and to vary the size of the writing spot in the sense of a decrease within at most substantially 100 milliseconds. The variation is for preference such that the writing spot size is changed between a first spot size intended for writing pattern areas each of a first predetermined area size and a second spot size smaller than the first spot size and intended for writing pattern areas each of a second predetermined area size smaller than the first predetermined area size. In dimensional terms, the writing spot can be varied between, for example, a diameter of substantially 2 nanometres and a diameter of substantially 200 nanometres.

The equipment can also include means for detecting any change in writing spot position and resolution consequent on variation in the spot size and for controlling the focusing means and displacing means to provide compensation for any detected change. This enables immediate correction of any transient offsets and losses of definition.

### BRIEF DESCRIPTION OF THE DRAWINGS

An embodiment of the present invention will now be more particularly described by way of example with reference to the accompanying drawings, in which:

FIG. 1 is a set of diagrams showing schematic forms of patterns to be written with different writing spot sizes of an electron beam in an electron beam lithography machine;

FIG. 2 is a schematic elevation of pattern-writing equipment of the prior art; and

FIG. 3 is a schematic elevation of pattern-writing equipment embodying the invention.

### DETAILED DESCRIPTION OF THE INVENTION

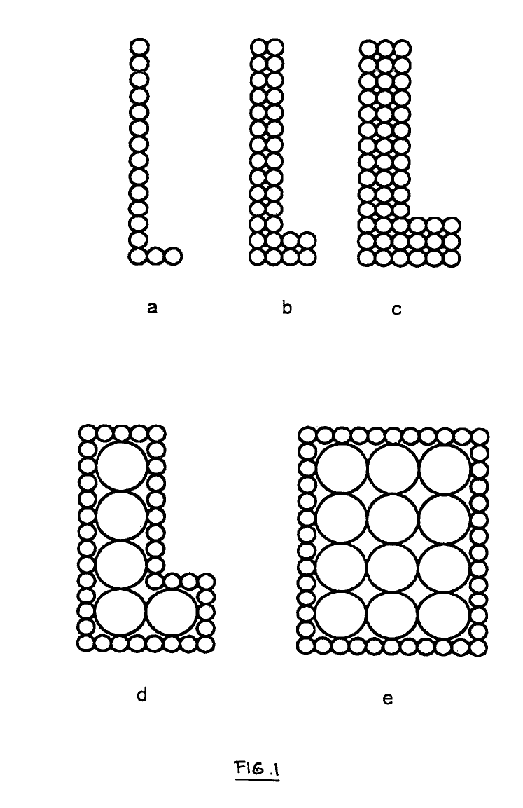

Referring now to the drawings there is shown in FIG. 1 a set of diagrams illustrating different possibilities of procedures for writing patterns, by way of an electron beam lithography machine, with pattern features of different sizes. In order to optimise writing throughout, it would be desirable to write small features with a small spot and low writing current and large features—or at least part of such features—with a large spot and high writing current. Patterns able to be written entirely by a small spot size are illustrated in diagrams a, b and c, whilst patterns able to be written by a combination of small spot size and large spot size are illustrated in diagrams d and e. It is always desirable to employ a small spot size at the edges of pattern features, as this ensures high pattern fidelity. A large spot size can be used in the pattern interior, however, where no fine detail is located and pattern fidelity is not an issue.

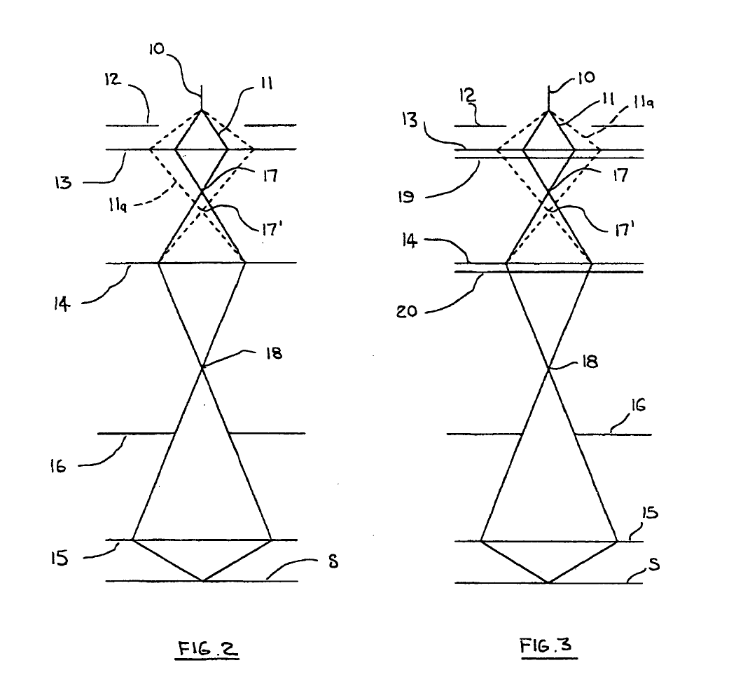

FIG. 2 shows the principal elements of a Gaussian electron beam column in a known electron beam lithography machine for high-throughput writing of pattern features on a substrate S, for example a mask for integrated circuits, with an electron-sensitive surface. The column comprises an electron source 10 which emits a beam of electrons having a cone-shaped envelope 11, an accelerating anode 12 at which the beam is accelerated by application of an electrostatic potential difference, or voltage, downstream of the electron source, and a series of three principal electromagnetic lens 13, 14 and 15 and a beam-defining aperture 16 for collectively influencing the electron beam to provide a defined writing spot on the substrate S. The writing spot is caused to scan the substrate surface by controlled deflection of the beam by a beam deflector (not illustrated) to trace the pattern on the surface.

The electron beam is focussed by the first lens 13 of the series to a first intermediate crossover focus 17 and refocused by the second lens 14 of the series to a second intermediate crossover focus 18. The beam-defining aperture 16 limits the amount of electron current. The aperture 16 is typically located at or near the plane of the second lens 14. The amount of electron current transmitted by the aperture 16 grows monotonically with the solid angle subtended by the cone of the beam envelope 11 at the plane of the electron source 10.

By decreasing the focal strength of the first lens 13 and simultaneously increasing the focal strength of the second lens 14 it is possible, by appropriate choice of the relative strengths of the lenses 13 and 14, to cause an increase in the amount of electron current passing through the aperture 16, but to leave the position of the second intermediate focus 18 unchanged. This can be understood by tracing the envelope 11a of the resulting changed beam, which is shown by the dashed lines and has a first intermediate crossover focus 17′ displaced relative to the focus 17 in direction towards the focus 18, back to the electron source 10. It is immediately evident that the solid angle of emission at the source 10 is larger for the envelope of the changed beam than for that of the original beam. The electron current transmitted through the aperture 16 is consequently larger in the changed beam envelope 11a.

The width of the first intermediate focus 17 is given by the width of the source 10 multiplied by the magnification of the first lens 13. The magnification of the lens 13 is given by the distance from that lens to the first intermediate focus 17, divided by the distance from the source 10 to the lens 13. Similarly, the width of the second intermediate focus 18 is given by the width of the first intermediate focus 17 multiplied by the magnification of the second lens 14. The magnification of the lens 14 is given by the distance thereof from the second intermediate focus 18, divided by the distance from the first intermediate focus 17 to the lens 14. It follows that the width of the second intermediate focus 18 is given by the width of the electron source times the magnification of the lens 13 times the magnification of the lens 14. It can be seen from the definition of the two magnifications that both are larger for the enlarged beam envelope 11a than for the original envelope 11. It follows from this that the width of the second intermediate focus 18 is larger for the enlarged beam envelope 11a than for the original beam envelope 11. Thus the condition of larger transmitted current is accompanied by a wider second intermediate focus 18. As the second intermediate focus 18 is transferred by the third lens 15 to the target surface of the substrate S, it follows that both the writing spot size and the writing current are larger for the changed envelope than for the original envelope, which is the desired result.

This method of varying the writing spot size and current is known, but the variation can be carried out only slowly, as conventional electron lenses capable of focussing an electron beam with a high accelerating voltage are of such a power that change in their focal strength is slow, typically over a period of seconds. This is a much larger time interval than the time required to write a pattern feature, usually measured in microseconds. It is therefore impractical to vary the spot size and writing current dynamically, i.e. while the pattern is being written.

This problem is overcome in the case of equipment embodying the invention as shown in FIG. 3 by adding two auxiliary electromagnetic lenses 19 and 20 near the planes of lens 13 and lens 14, respectively. The auxiliary lenses 19 and 20 are used only to vary the position of the first intermediate focus between the focus 17 and the focus 17′, whilst the main imaging action is still effected by the lenses 13 and 14. The auxiliary lenses 19 and 20 can therefore be significantly weaker than the lenses 13 and 14. A weaker lens can be switched more quickly than a strong lens. Being relatively weak, the auxiliary lenses 19 and 20 can therefore be varied at a rate comparable with a desired faster rate of pattern writing.

The auxiliary lenses 19 and 20 are caused to switch synchronously with each other and with a stream of pattern information supplied to a pattern-writing control system of the column while the strong lenses 13 and 14 maintain constant excitation. The switching between beam writing spot sizes is managed by means of a high-speed electronic switching device. Switching from smaller to larger spot size is accomplished in less than 10 milliseconds and switching from larger to smaller spot size in less than 100 milliseconds. This latter switching is more difficult, due to the precision of focus required for the smaller spot size, whereas the focus for the larger spot size is not critical. The diameter of the smaller spot size can be, for example, substantially 2 nanometres and that of larger spot size up to substantially 200 nanometres.

If any change in the position of the writing spot on the substrate S and/or change in the resolution of the spot should occur as a result of the variation in spot size, this can be detected—inclusive of measurement of the amount of change—and automatically eliminated by appropriate compensating change, in particular adjustment of the beam focus and deflection of the beam.

Caution is required not to excite eddy currents in the surrounding conductive metal parts of the electron column. Eddy currents give rise to focussing effects which ultimately degrade the switching speed of the device. To this end, the usual metal parts of aluminium and steel in the supports of the coils of the auxiliary lens are replaced with parts made from a high-resistivity—for example 170 ohm cm or higher—alloy of titanium, aluminium and vanadium. This alloy has a resistivity of such a level that eddy currents, while present, do not pose a problem.

A special high-speed lens driver circuit is used, as electromagnetic lenses are not switched at high speed. In fact, such lenses conventionally operate in static mode, with no time variation of the excitation. In addition, the inductance of the coils of the auxiliary lenses is maintained as low as possible, consistent with the change in focal length required. This facilitates high-speed switching by minimising the requirements imposed on the switching electronics.

It is desirable for the compliance voltage of the drive circuitry to be as high as possible, for example 128 volts, to overcome the transient time delay during switching of the coils.

The column control systems are extended to include computer hardware and software to cause the lenses to switch in synchronism with supplied pattern data. The rate of pattern data transfer is preferably as high as possible, with bit rates of typically 25 MHz or higher.

In optical terms, switching of the two auxiliary lenses in synchronism causes the electron optical magnification of the column to change dynamically. A large writing spot requires a relatively large magnification, while a small writing spot requires a relatively small magnification. This change in magnification as described in the foregoing is accomplished in a way which maintains an intermediate crossover position in a beam blanking section of the column.

1. Pattern-writing equipment for writing a pattern on a substrate surface by electron beam lithography, comprising generating means for generating an electron beam, focusing means for focusing the beam to produce a defined writing spot on an electron-sensitive surface of the substrate, displacing means for displacing the writing spot on the surface in correspondence with the pattern to be written and control means for varying the size of the writing spot to produce a simultaneous increase or decrease in both the spot size and the writing current of the beam, wherein the focusing means has two lens sets arranged in series to focus the beam and each comprising a main lens and an auxiliary lens with a lower focal strength than that of the main lens of the respective set, the control means being operable to vary the writing spot size by reciprocal change in the focal strengths of the auxiliary lenses of the two lens sets during writing of the pattern.

2. The equipment according to claim 1, wherein each auxiliary lens is arranged adjacent to the main lens of the respective set.

3. The equipment according to claim 1, wherein each auxiliary lens is arranged directly downstream of the main lens of the respective set with respect to the generating means.

4. The equipment according to claim 1, wherein the lens sets are arranged to focus the beam at two intermediate crossover foci and the control means is operable to vary the focal strengths of the auxiliary lenses to change the relative spacing of the intermediate foci.

5. The equipment according to claim 1, wherein the control means is operable to change the focal strengths of the auxiliary lenses substantially simultaneously.

6. The equipment according to claim 1, further comprising a pattern-writing control system for supplying pattern-writing data to control displacement of the beam by the displacing means, the control means being operable to vary the focal strengths of the auxiliary lenses in synchronism with the displacement of the beam.

7. The equipment according to claim 1, wherein at least one of the lenses is an electromagnetic lens.

8. The equipment as claimed in claim 7, wherein the at least one electromagnetic lens is an auxiliary lens with a coil having a minimised inductance.

9. The equipment as claimed in claim 7, wherein the at least one lens is an auxiliary lens and that lens is carried by a support of a high-resistivity alloy.

10. The equipment according to claim 1, wherein at least one of the lenses is an electrostatic lens.

11. The equipment as claimed in claim 10, wherein the at least one electrostatic lens is an auxiliary lens with a coil having a minimised inductance.

12. The equipment as claimed in claim 10, wherein the at least one lens is an auxiliary lens and that lens is carried by a support of a high-resistivity alloy.

13. The equipment according to claim 1, wherein the control means is operable to vary the size of the writing spot in the sense of an increase within at most substantially 10 milliseconds.

14. The equipment according to claim 1, wherein the control means is operable to vary the size of the writing spot in the sense of a decrease within at most substantially 100 milliseconds.

15. The equipment according to claim 1, wherein the control means is operable to vary the writing spot size between a first spot size for writing pattern areas each of a first predetermined area size and a second spot size smaller than the first spot size and for writing pattern areas each of a second predetermined area size smaller than the first predetermined area size.

16. The equipment according to claim 1, wherein the control means is operable to vary the writing spot size between a diameter of substantially 2 nanometres and a diameter of substantially 200 nanometres.

17. The equipment according to claim 1, comprising means for detecting any change in writing spot position and resolution consequent on variation in the spot size and for controlling the focusing means and displacing means to provide compensation for any detected change.
